(19) United States
(12) Patent Application Publication
(10) Pub. No.: US 2010/0213586 A1
(43) Pub. Date: Aug. 26, 2010

(54) SEMICONDUCTOR PACKAGE AND MANUFACTURING METHOD THEREOF

(75) Inventor: Yoshio Fukuda, Ebino-shi (JP)

Correspondence Address: Dickstein Shapiro LLP, 2049 Century Park East, Suite 700, Los Angeles, CA, 90067, US

(73) Assignee: YAMAHA CORPORATION, Hamamatsu-shi (JP)

(21) Appl. No.: 12/707,598

(22) Filed: Feb. 17, 2010

(30) Foreign Application Priority Data
Feb. 20, 2009 (JP) 2009-038319

(51) Int. Cl. H01L 23/495; H01L 21/56

(52) U.S. Cl. 257/666; 438/123; 257/E23.031; 257/E21.502

(57) ABSTRACT

A semiconductor package is constituted of a semiconductor chip, a rectangular-shaped stage having the semiconductor chip mounted on the surface, a plurality of leads which are aligned in the periphery of the stage and which are electrically connected to the semiconductor chip, and a resin mold which seals the semiconductor chip, the stage, and the leads therein while externally exposing the backside of the stage on the lower surface thereof. In particular, at least one protrusion is further formed on the upper surface or the lower surface of the resin mold at a position within the outer portion of the resin mold disposed outside the sealed portion of the resin mold. The height of the outer portion of the resin mold having the protrusion is larger than the sum of the thickness of the stage and the thickness of the sealed portion of the resin mold.

### BACKGROUND OF THE INVENTION

1. Field of the Invention

The present invention relates to semiconductor packages that encapsulate semiconductor chips mounted on stages of lead frames sealed with resin molds. The present invention also relates to manufacturing methods of semiconductor packages.

The present application claims priority on Japanese Patent Application No. 2009-38319, the content of which is incorporated herein by reference.

2. Description of the Related Art

Various semiconductor packages have been developed and disclosed in various documents such as Patent Document 1. In semiconductor packages, semiconductor chips are mounted on the surfaces of rectangular-shaped stages of lead frames sealed with resin molds. For the purpose of efficiently dissipating heat from semiconductor chips, the backsides of stages are not sealed with resin molds but are exposed externally. In semiconductor packages, plating is applied to the backsides of stages so as to improve soldering wettability since the backsides of stages are entirely soldered to circuit boards in order to dissipate heat of semiconductor chips via circuit boards. In this connection, plating is performed after the formation of resin molds.

Patent Document 1: Japanese Patent Application Publication No. 2000-150725

Semiconductor packages are assembled together after plating and are collectively transported to predetermined destinations. During the transportation of semiconductor packages which are vertically assembled, plating applied to the backside of a stage of an “upper” semiconductor package may be stuck to a resin mold of a “lower” semiconductor package so that plating may be partially taken away.

When plating is applied to numerous semiconductor packages, it is necessary to interpose spacers between upper and lower semiconductor packages which are vertically assembled. Interposing spacers between semiconductor packages is troublesome and is likely to reduce the manufacturing efficiency of semiconductor packages.

### SUMMARY OF THE INVENTION

It is an object of the present invention to provide a semiconductor package which simplifies plating on the backside of a stage with its surface mounting a semiconductor chip thereon and which prevents plating from being taken away.

A semiconductor package of the present invention is constituted of a semiconductor chip, a rectangular-shaped stage having the semiconductor chip mounted on the surface, a plurality of leads which are aligned in the periphery of the stage and which are electrically connected to the semiconductor chip, and a resin mold which seals the semiconductor chip, the stage, and the leads therein while externally exposing the backside of the stage on the lower surface thereof. In particular, at least one protrusion is further formed on the upper surface or the lower surface of the resin mold at a position within the outer portion of the resin mold disposed outside the sealed portion of the resin mold. The height of the outer portion of the resin mold having the protrusion is larger than the sum of the thickness of the stage and the thickness of the sealed portion of the resin mold.

When a plurality of semiconductor packages is vertically assembled, the protrusion formed on the upper surface of the outer portion of the resin mold of the lower semiconductor package is brought into contact with the lower surface of the outer portion of the resin mold of the upper semiconductor package, or the protrusion formed on the lower surface of the outer portion of the resin mold of the upper semiconductor package is brought into contact with the upper surface of the outer portion of the resin mold of the lower semiconductor package. Thus, a gap corresponding to the protrusion is formed between the exposed backside of the stage of the upper semiconductor package and the upper surface of the resin mold of the lower semiconductor package. Due to such a gap, it is possible to reliably prevent the exposed backside of the stage of the upper semiconductor package from coming in contact with the upper surface of the resin mold of the lower semiconductor package, thus preventing the plating applied to the backside of the stage from being taken away.

Due to the formation of the protrusion, the present invention does not needs a conventional spacer interposed between vertically adjacent semiconductor packages. This simplifies plating applied to the backside of the stage of each semiconductor package, thus improving the manufacturing efficiency of semiconductor packages.

When a plurality of semiconductor packages is vertically assembled after plating, it is possible to prevent the plating applied to the backside of the stage of the upper semiconductor package from being struck to the upper surface of the resin mold of the lower semiconductor package.

In the above, the protrusion is formed in a loop shape encompassing the sealed portion of the resin mold in plan view. Alternatively, a plurality of protrusions is disposed axisymmetrically about an axis that is vertically extended at the center of the backside of the stage.

A manufacturing method of the above semiconductor package includes a lead frame preparation step in which a thin metal plate is processed so as to prepare the above lead frame, a semiconductor chip mounting step in which the semiconductor chip is mounted on the surface of the stage and is electrically connected to the leads, a molding step in which the resin mold is formed to seal the semiconductor chip, the stage, and the leads therein while exposing the backside of the stage externally on the lower surface thereof, and a plating step in which plating is applied to the backside of the stage and the backsides of the leads which are exposed externally from the resin mold. In the molding step, at least one protrusion is formed on the upper surface or the lower surface of the resin mold at a position within the outer portion of the resin mold disposed outside the sealed portion of the resin mold. The height of the outer portion of the resin mold having the protrusion is larger than the sum of the thickness of the stage and the thickness of the sealed portion of the resin mold.

Prior to the plating step, the lead frame is vertically assembled with a second lead frame having the same constitution as the lead frame in such a way that the backside of the stage of the lead frame is slightly distanced from the upper surface of the resin mold of the second lead frame with a gap corresponding to the protrusion therebetween. Then, plating is applied to the lead frame together with the second lead frame.

### BRIEF DESCRIPTION OF THE DRAWINGS

These and other objects, aspects, and embodiments of the present invention will be described in more detail with reference to the following drawings.

FIG. 1 is a plan view showing a semiconductor package according to a preferred embodiment of the present invention, which is adjoined to another semiconductor package via a thin metal plate.

FIG. 2 is a backside view of the semiconductor package viewed from the lower surface of a resin mold.

FIG. 3 is a sectional view taken along line A-A in FIGS. 1 and 2.

FIG. 4 is a backside view of a lead frame used for manufacturing the semiconductor package of FIG. 1.

FIG. 5 is an illustration partly in section showing two semiconductor packages of FIG. 3 are vertically assembled together.

FIG. 6 is a plan view showing a variation of the semiconductor package having four dot-shaped protrusions formed in the four corners on the surface of the resin mold.

FIG. 7 is a plan view showing another variation of the semiconductor package having two dot-shaped protrusions formed in the two opposite corners on the surface of the resin mold.

FIG. 8 is a sectional view showing two semiconductor packages, each having a single dot-shaped protrusion in one corner of the surface of the resin mold, which are vertically assembled.

FIG. 9 is a sectional shape showing a quad flat package as a further variation of the semiconductor package of the present embodiment.

### DESCRIPTION OF THE PREFERRED EMBODIMENT

The present invention will be described in further detail by way of examples with reference to the accompanying drawings.

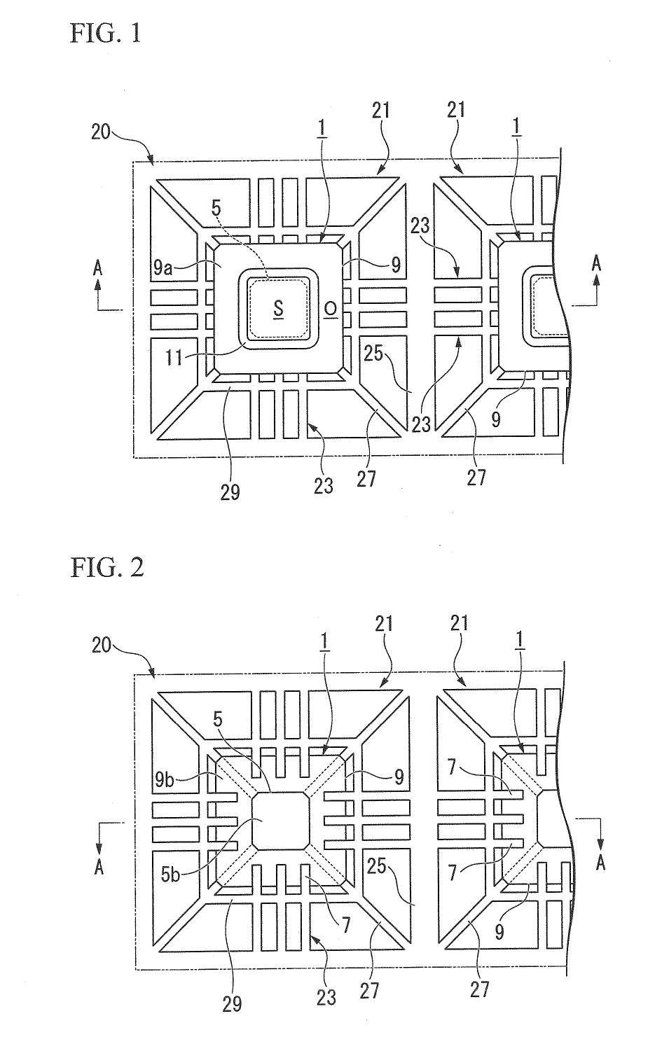

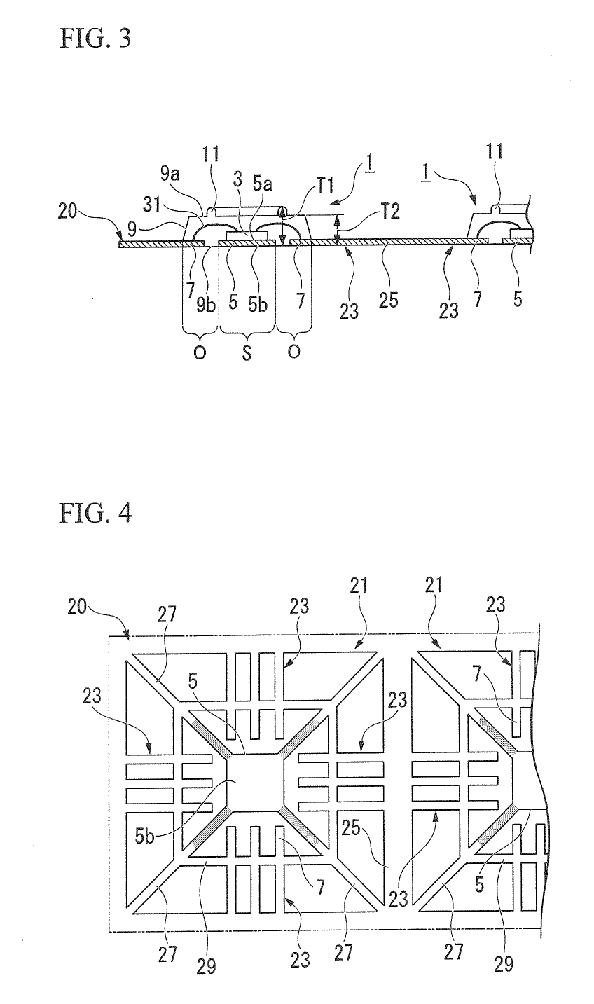

A semiconductor package 1 according to a preferred embodiment of the present invention will be described with reference to FIGS. 1 to 5. A plurality of semiconductor packages (each corresponding to the semiconductor package 1 of the present embodiment) is unified to adjoin together via a thin metal plate 20 and is then divided into individual pieces in the final stage of manufacturing.

As shown in FIGS. 1 to 3, the semiconductor package 1 is constituted of a semiconductor chip 3, a rectangular-shaped stage 5 with a surface 5a mounting the semiconductor chip 3 thereon, a plurality of inner leads 7 which are disposed in the periphery of the semiconductor chip 3 and are electrically connected to the semiconductor chip 3, and a resin mold 9 which seals the semiconductor chip 3, the stage 5, and the inner leads 7 therein.

The stage 5 and the inner leads 7 are formed in a lead frame 21 which is used to produce the semiconductor package 1. As shown in FIG. 4, a plurality of lead frames (each corresponding to the lead frame 21 having a single stage 5) is aligned in a single line or in plural lines and is collectively formed by performing press working and etching on the thin metal plate 21. The following description refers to a single unit of the lead frame 21 having a single stage 5.

The lead frame 21 is constituted of the stage 5 having a rectangular shape in plan view, a plurality of leads 23 disposed in the periphery of the stage 5, a frame 25 that interconnects the leads 23 together, and a plurality of interconnection leads 27 that interconnect the stage 5 and the frame 25 together. The internal rim of the frame 25 is formed in a rectangular shape in plan view encompassing the stage 5 therein. In the thin metal plate 20, the frame 25 is shared by two lead frames which adjoin together.

The four sides of the stage 5 are disposed along the four sides of the frame 25. A plurality of leads 23 is extended inwardly from each of four sides of the inner rim of the frame 25 toward the stage 5, wherein gaps are interposed between the distal ends of the leads 23 and each of four sides of the stage 5. In this connection, the leads 23 are each extended in the direction perpendicular to each side of the stage 5 and each side of the inner rim of the frame 25. The interconnection leads 27 are extended inwardly from the four corners of the inner rim of the frame 25 toward the four corners of the stage 5.

The end portions of the leads 23 constitute the inner leads 7 of the semiconductor package 1, and the internal portions of the interconnection leads 27 (which are positioned close to the stage 5) constitute the semiconductor package 1.

A dam bar 29 is formed to interconnect the midpoints of the leads 23 and the midpoints of the interconnection leads 27 in their longitudinal directions. The dam bar 29 is formed in a rectangular loop shape in plan view, having four sides which lie in parallel to the four sides of the stage 5 and the four sides of the frame 25.

The lead frame 21 is entirely formed with the same thickness as the thin metal plate 20, wherein only the internal portions of the interconnection leads 27 disposed between the stage 5 and the dam bar 29 are reduced in thickness compared to the original thickness of the thin metal plate. The internal portions of the interconnection leads 27 are disposed on a backside 5b of the stage 5 opposite to the surface 5a mounting the semiconductor chip 3 thereon, wherein the backsides of the internal portions of the interconnection leads 27 are subjected to half-etching and are thus slightly higher than the backside 5b of the stage 5. In FIG. 4, hatching areas indicate the half-etched backsides of the internal portions of the interconnection leads 27.

The resin mold 9 of the semiconductor package 1 seals the internal area of the lead frame 21 positioned inside the dam bar 29, including the stage 5, the distal ends of the leads 23 (constituting the inner leads 7), and the internal portions of the interconnection leads 27. The resin mold 9 is formed like a thick rectangular plate in plan view, wherein the four sides thereof are disposed along the four sides of the dam bar 29.

The backside 5b of the stage 5 and the inner leads 7 are exposed externally on a planar lower surface 9b of the resin mold 9 in view of the thickness direction of the stage 5. Since the backsides of the internal portions of the interconnection leads 27 are slightly higher than the backside 5b of the stage 5, they are not exposed externally on the lower surface 9b of the resin mold 9.

An upper surface 9a of the resin mold 9 is a planar surface which is positioned above and parallel to the surface 5a of the stage 5. A protrusion 11 having a rectangular loop shape in plan view is formed on the upper surface 9a of the resin mold 9.

The protrusion 11 is formed in an outer portion O of the resin mold 9 outside a sealed portion (or a laminated portion) S of the resin mold whose horizontal area overlaps the area of the backside 5b of the stage 5 in plan view and which covers the stage 5 in its thickness direction. Specifically, the protrusion 11 is positioned between the distal ends of the inner leads 7 and the stage 5 within the outer portion O of the resin mold 9 in plan view. In other words, the protrusion 11 is positioned not to overlap the exposed portion of the lead frame 21 (which is exposed externally on the lower surface 9b of the resin mold 9) in plan view.

Thus, a thickness T1 at the outer portion O of the resin mold having the protrusion 11 is larger than a thickness T2 corresponding to the sum of the thickness of the stage 5 and the thickness of the sealed portion S of the resin mold 9.

Next, a manufacturing method of the semiconductor package 1 will be described below.

(a) Lead Frame Preparation Step

First, a plurality of lead frames (each corresponding to the lead frame 21) is prepared by use of the thin metal plate 20.

(b) Semiconductor Chip Mounting Step

Subsequently, the semiconductor chip 3 is attached onto the surface 5a of the stage 5 and is electrically connected to the distal ends of the leads 23 (i.e. the inner leads 7) via bonding wires 31.

(c) Molding Step

The resin mold 9 is formed to seal the semiconductor chip 3, the stage 5, the leads 23, and the internal portions of the interconnection leads 27 while externally exposing the backside 5b of the stage 5 and the backsides of the leads 23. In this step, the lead frame 21 is put into a metal mold whose interior shape corresponds to the exterior shape of the resin mold 9 having the protrusion 11, into which a melted resin is injected so as to form the resin mold 9.

After the molding step, the semiconductor package 1 adjoined to another semiconductor package 20 via the thin metal plate 20 is produced as shown in FIGS. 1 to 3.

(d) Plating Step

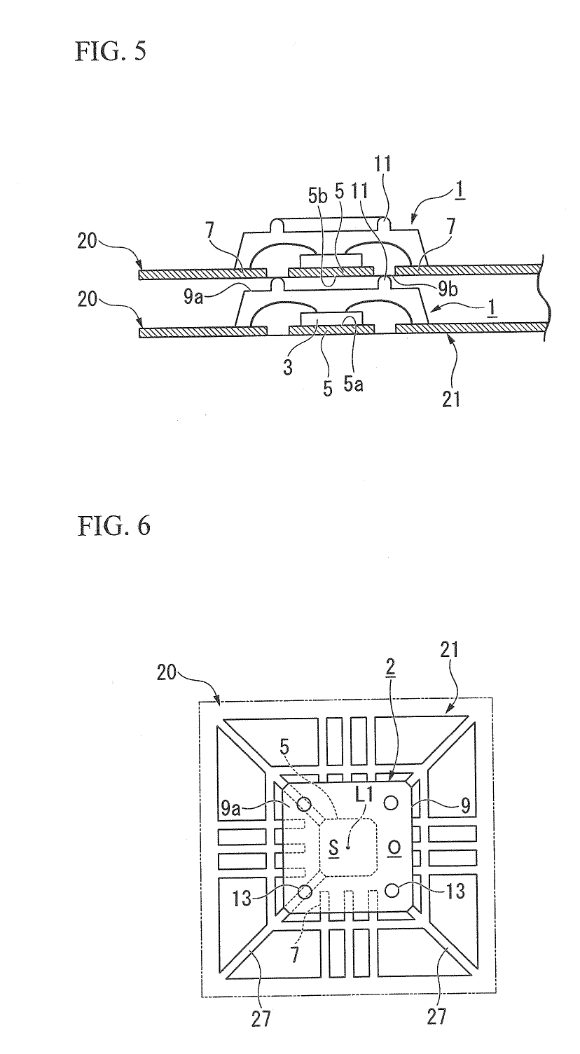

After the molding step, plating is applied to the exposed portion of the stage 5 and the exposed portions of the leads 23, which are exposed externally from the resin mold 9. The plating step is performed in the condition of FIG. 5 in which a plurality of semiconductor packages 1 already subjected to the lead frame preparation step, the semiconductor chip mounting step, and the molding step is vertically assembled. That is, a plurality of thin metal plates 20 each having a plurality of lead frames 21 is prepared in the lead frame preparation step and is then sequentially subjected to the semiconductor chip mounting step and the molding step, whereby a plurality of thin metal plates 20 is assembled together so as to vertically assemble a plurality of stages 5.

In the above, two lead frames 21 are vertically assembled in such a way that the protrusion 11 of the resin mold 9 of the “lower” lead frame 21 is brought into contact with the lower surface 9b of the resin mold 9 of the “upper” lead frame 21, namely the prescribed area of the lower surface 9b interposed between the stage 5 and the distal ends of the inner leads 7 in plan view within the outer portion O of the resin mold 9. In the contact state, the backside 5b of the stage 5 and the inner leads 7 which are exposed externally on the lower surface 9b of the resin mold 9 of the upper lead frame 5 is slightly distanced from the upper surface 9a of the resin mold 9 of the lower lead frame 21 with a gap formed therebetween. Due to such a gap, it is possible to prevent the backside 5b of the stage 5 and the inner leads 7 of the “upper” semiconductor package 1 from unexpectedly coming in contact with the resin mold 9 of the “lower” semiconductor package 1.

As described above, a plurality of semiconductor packages 1 is vertically assembled and then subjected to plating. The plating step is performed in such a way that a plurality of semiconductor packages 1 vertically assembled is soaked in a plating bath filled with a plating solution, for example. Since all the semiconductor packages 1 have the backsides 5b of the stages 5 and the backsides of the inner leads 7 exposed externally from the resin molds 9, plating is applied to the backsides 5b of the stages 5 and the backsides of the inner leads 7.

(e) Cutting Step

The leads 23 and the interconnection leads 27 interposed between the resin molds 9 and the dam bars 29 are subjected to cutting, thus producing an individual piece of the semiconductor packages 1. After the cutting step, the semiconductor package 1 is configured such that the cutting faces of the leads 23 and the interconnection leads 27 are exposed externally on the lateral sides of the resin mold 9.

According to the present embodiment of the semiconductor package 1 and its manufacturing method, it is unnecessary to dispose conventional spacers between the lead frames 21 vertically assembled, and it is possible to apply plating to the backsides 5b of the stages 5 of the semiconductor packages 1 which are simply assembled together. Thus, it is possible to simplify the plating operation and to improve the manufacturing efficiency of the semiconductor packages 1.

After the plating step, even when a plurality of semiconductor packages 1 is vertically assembled, it is possible to reliably prevent the plating applied to the backside 5b of the stage 5 and the backsides of the inner leads 7 of the “upper” semiconductor package 1 from being stuck to the upper surface 9a of the resin mold 9 of the “lower” semiconductor package 1. In other words, even when a plurality of semiconductor packages 1 already subjected to plating is vertically assembled, it is possible to reliably prevent the plating layers from being taken away from the backside 5b of the stage 5 and the backsides of the inner leads 7.

In the manufacturing method of the present embodiment, a plurality of semiconductor packages 1 which are interconnected using the thin metal plate 20 is vertically assembled and collectively subjected to plating. Instead, the plating step can be performed after the cutting step so that the semiconductor packages 1 are divided into individual pieces, assembled together, and then subjected to plating. In addition, the lead frame preparation step can be modified such that a single lead frame 21 is extracted from each thin metal plate 20.

The top area of the protrusion 11 having a rectangular loop shape in plan view is maintained in the same plane in a circumferential direction, in other words, the same height is maintained in the projection 11 along its circumferential direction. This makes it possible to vertically assemble a plurality of semiconductor packages 1 in a stable manner. Even when the plating step is performed after the cutting step, it is possible to apply plating to the cutting faces of the leads 23 and the cutting faces of the interconnection leads 27, which are exposed externally from the lateral sides of the resin mold 9.

The present embodiment is not necessarily designed such that the protrusion 11 having a rectangular loop shape in plan view is formed on the upper surface 9a of the resin mold 9. Instead, it is possible to form a plurality of protrusions each having a dot shape as shown in FIGS. 6 to 8.

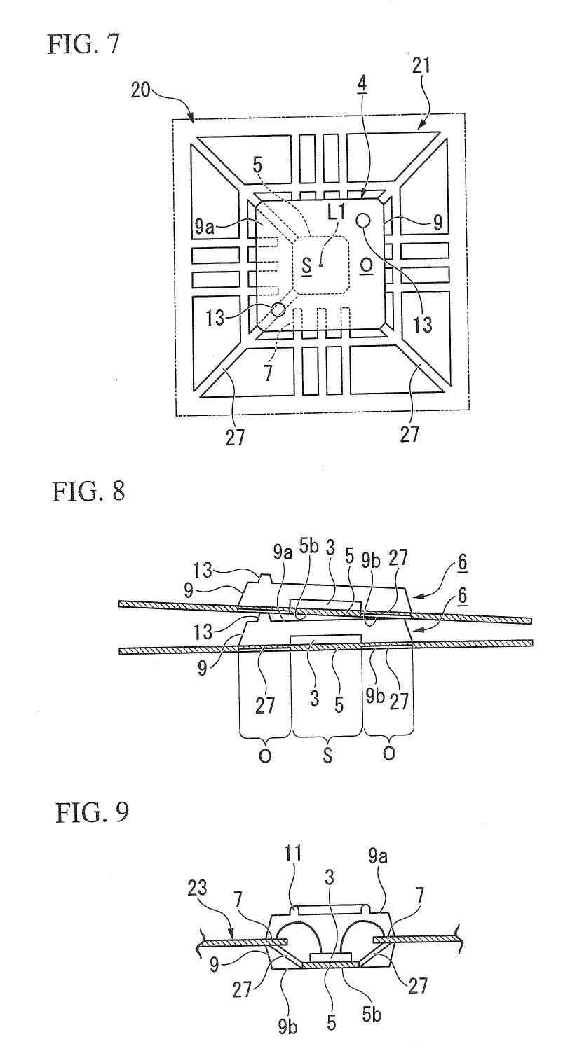

FIG. 6 shows a semiconductor package 2 in which four dot-shaped protrusions 13 are formed in the four corners on the upper surface 9a of the resin mold 9. FIG. 7 shows a semiconductor package 4 in which two dot-shaped protrusions 13 are formed in two opposite corners on the upper surface 9a of the resin mold 9. The protrusions 13 shown in FIGS. 6 and 7 are axisymmetrically positioned about a center axis L1 which is extended in the thickness direction of the stage 5 at the center of the backside 5b. FIG. 8 shows a semiconductor package 6 in which a single dot-shaped protrusion 1 is formed in one corner on the upper surface 9a of the resin mold 9. All the above protrusions 13 are positioned vertically relative to the interconnection leads 27.

The above variations having the protrusions 13 are not necessarily designed in a similar manner with the aforementioned embodiment such that the protrusions 13 are formed at positions within the outer portion O of the resin mold 9 vertically relative to the inner leads 7. That is, the protrusions 13 can be formed at arbitrary positions within the outer portion O of the resin mold 9 except for a certain portion of the resin mold 9 vertically relative to the inner leads 7 and the stage 5. Each of the semiconductor packages 2, 4, and 6 shown in FIGS. 6, 7, and 8 allows the protrusion(s) 13 to be formed within the outer portion O of the resin mold 9 outside a certain portion of the resin mold 9 vertically relative to the inner leads 7 and the stage 5, but it can achieve a similar effect as the present embodiment.

In the assembled state in which plural individual pieces of the semiconductor packages 6 each having a single dot-shaped protrusion 13 are vertically assembled, the upper surface 9a of the resin mold 9 of the “lower” semiconductor package 6 is brought into contact with the lower surface 9b of the resin mold 9 of the “upper” semiconductor package 6 at the opposite corner, which is positioned opposite to one corner just above the protrusion 13 and in which no exposed portion of the lead frame 21 exists in the lower surface 9b of the resin mold 9. Therefore, similar to the semiconductor package 1 of the present embodiment, the upper surface 9a of the resin mold 9 of the lower semiconductor package 6 is slightly distanced from the lower surface 9b of the resin mold 9 of the upper semiconductor package 6, in which the backside 5b of the stage 5 and the backside of the inner leads 7 are exposed externally, so that a gap be formed between the backside 5b of the stage 5 and the upper surface 9a of the resin mold 9 and between the backside of the inner leads 7 and the upper surface 9a of the resin mold 9. Thus, it is possible to reliable prevent the stage 5 and the inner leads 7 of the upper semiconductor package 6 from coming in contact with the resin mold 9 of the lower semiconductor package 6.

It is possible to vertically assemble a plurality of semiconductor packages 4 shown in FIG. 7 in a stable manner after the cutting step, since the top areas of the three or more protrusions 13 that are positioned axisymmetrically about the center axis L1 extended in the thickness direction of the stage 5 at the center of the backside 5b of the stage 5 are positioned in the same plane.

In this connection, it is possible to form the dot-shaped protrusions 13 by use of ejector pins of a metal mold (not shown) used in the molding step, wherein ejector pins are originally used to draw a molded article corresponding to the resin mold 9. It is possible to form planar faces on the top areas of the protrusions 13. It is possible to imprint a cavity number indicating an identification number of a metal mold on the top area of the protrusion 13.

The semiconductor packages 1, 2, 4, and 6 are designed such that the protrusions 11 and 13 are each formed on the “planar” upper surface 9a of the resin mold 9; but this is not a restriction. Instead of forming the protrusions 11 and 13, it is possible to partially raise the height of the upper surface 9a of the resin mold 9 in the outer portion O rather than the sealed portion S. For example, a step difference is formed between the sealed portion S and the outer portion O on the upper surface 9a of the resin mold 9, thus forming a protrusion. Alternatively, the upper surface 9a of the resin mold 9 is formed in a concaved or recessed shape so that the lower area thereof constitutes the sealed portion S while the higher area thereof constitutes the protrusion.

The protrusions 11 and 13 are not necessarily formed to protrude upwardly from the upper surface 9a of the resin mold 9, since the present embodiment requires that the thickness of the outer portion O of the resin mold 9 having the protrusion 11 or 13 be larger than the sum of the thickness of the sealed portion S of the resin mold 9 and the thickness of the stage 5. For this reason, a protrusion can be formed to protrude downwardly from the lower surface 9b of the resin mold 9.

The above variation in which at least one protrusion is formed on the lower surface 9b of the resin mold 9 can achieve the same effect as the aforementioned embodiment. In addition, it is possible to form at least one hole suiting to the above projection in the circuit board, which is brought into contact with the backside 5b of the stage 5. This makes it easy to establish the desired positioning of the semiconductor package whose projection is inserted into the hole of the circuit board.

The semiconductor packages 1, 2, 4, and 6 are QFN (Quad Flat Non-Leaded) packages in which the inner leads 7 are exposed externally on the lower surface 9b of the resin mold 9; but the present embodiment simply requires that the backside 5b of the stage 5 is exposed externally on the lower surface 9b of the resin mold 9. Therefore, it is possible to redesign the present embodiment in the form of a QFP (i.e. a quad flat package) in which the inner leads 7 are not exposed externally but embedded inside the resin mold 9, and the base portions of the leads 23 connected to the inner leads 7 serve as outer leads which project externally from the lateral sides of the resin mold 9.

Lastly, the present invention is not necessarily limited to the present embodiment and its variations, which can be further modified within the scope of the invention as defined in the appended claims.

What is claimed is:

1. A semiconductor package comprising:
a semiconductor chip;
a rectangular-shaped stage having the semiconductor chip mounted on the surface;
a plurality of leads which are aligned in the periphery of the stage and which are electrically connected to the semiconductor chip;
a resin mold which seals the semiconductor chip, the stage, and the leads therein while externally exposing the backside of the stage on a lower surface thereof; and
at least one protrusion which is formed on an upper surface of the resin mold at a position within an outer portion of the resin mold disposed outside a sealed portion of the resin mold which covers the backside of the stage in plan view and which seals the stage in its thickness direction,
wherein a height of the outer portion of the resin mold having the protrusion is larger than the sum of the thickness of the stage and the thickness of the sealed portion of the resin mold.

2. The semiconductor package according to claim 1, wherein the protrusion is formed in a loop shape encompassing the sealed portion of the resin mold in plan view.

3. The semiconductor package according to claim 1, wherein a plurality of protrusions is disposed axisymmetrically about an axis that is vertically extended at the center of the backside of the stage.

4. A manufacturing method of a semiconductor package comprising:
processing a thin metal plate so as to prepare a lead frame including a rectangular-shaped stage, a plurality of leads aligned in the periphery of the stage, a frame that interconnects the leads so as to encompass the stage, and a plurality of interconnection leads that interconnect the frame and the stage together;
mounting a semiconductor chip on the surface of the stage and electrically connecting the semiconductor chip with the leads;
sealing the semiconductor chip, the stage, and the leads with a resin mold while exposing the backside of the stage externally on a lower surface of the resin mold;
forming at least one protrusion on an upper surface of the resin mold at a position within an outer portion of the resin mold disposed outside a sealed portion of the resin mold which covers the backside of the stage in plan view and which seals the stage in its thickness direction, wherein a height of the outer portion of the resin mold having the protrusion is larger than the sum of the thickness of the stage and the thickness of the sealed portion of the resin mold; and
applying plating to the backside of the stage and the backsides of the leads which are exposed externally from the resin mold.

5. The manufacturing method of a semiconductor package according to claim 4, wherein prior to the plating, the lead frame is vertically assembled with a second lead frame having the same constitution as the lead frame in such a way that the backside of the stage of the lead frame is slightly distanced from the upper surface of the resin mold of the second lead frame with a gap corresponding to the protrusion therebetween, and then the plating is applied to the lead frame together with the second lead frame.
